(19) United States
(12) Patent Application Publication
(10) Pub. No.: US 2023/0154698 A1
(43) Pub. Date: May 18, 2023

(54) MULTI-POSITION KEYBOARD KEY SWITCH

(71) Applicant: MECHANICAL KEYBOARDS, LLC, CHANDLER, AZ (US)

(72) Inventor: JOEL TUBRE, PHOENIX, AZ (US)

(73) Assignee: MECHANICAL KEYBOARDS, LLC, CHANDLER, AZ (US)

(21) Appl. No.: 18/157,956

(22) Filed: Jan. 23, 2023

Related U.S. Application Data
(63) Continuation of application No. 17/397,943, filed on Aug. 9, 2021.

(51) Int. Cl. H01H 13/14; H01H 13/04; G01R 33/07; H01H 13/50; H01H 13/64

(52) U.S. Cl. CPC H01H 13/14; H01H 13/04; G01R 33/07; H01H 13/503; H01H 13/64

(57) ABSTRACT

Provided is a multi-position electrical switch. The multi-position switch includes an enclosure and a stem structured and arranged to move along a vertical axis within the enclosure. The stem provides a plurality of distinct horizontal protrusions as physical deactivators at different elevations along the vertical axis. A plurality of distinct electrical contacts are provided by a paired stationary element and a movable element for flexibly making and breaking electrical contact with the stationary element, the movable element biased for contact with the stationary element. Each distinct electrical contact is associated with at least one distinct horizontal protrusion. A spring disposing the stem in an initial position in which the plurality of distinct horizontal protrusions dispose all of the movable elements in broken contact. Depression of the stem along the vertical axis transitions the distinct horizontal protrusions away from the movable elements permitting contact with their paired stationary elements.

### CROSS REFERENCE TO RELATED APPLICATIONS

The present application is continuation of U.S. patent application Ser. No. 17/397,943 filed on Aug. 9, 2021 and entitled DUAL CONDUCTIVE KEY SWITCH, the disclosure of which is incorporated herein by reference. Moreover, this continuation claims the benefit of the filing date of U.S. patent application Ser. No. 17/397,943 filed on Aug. 9, 2021.

### FIELD OF THE INVENTION

The present invention relates generally to the field of keyboard switches, and more specifically and particularly, to a multi-position key switch—a single switch having more than one state of conducting when depressed.

### BACKGROUND

At the present, users of keyboards are familiar with the typical operation of a key when depressed—a single letter or number is generally displayed on a monitor or screen when alpha numeric keys are depressed, and various functions may be performed when other keys are depressed.

More specifically stated, each key when depressed results in a single trigger—typically a conductive trigger, but key switches may also operate with induction, capacitive-coupling, optical triggers, or other such methods or systems that can detect when a key has been depressed and result in a signal that such an action has occurred.

While the typical keyboard may appear to offer more than one option for at least some key switches—capital letters vs lower case, numbers vs symbols, and function keys vs system adjustments, etc . . . this duality of behavior is actually dependent upon the user depressing yet another key first—a Shift, Control, Command, or other key.

Moreover, the same key for the lower case “a” and the capital “A” is depressed, and the same signal of its depression is received—the determination of a lower case or capital letter being dependent not on how the key itself was depressed, but on whether or not another key was depressed to indicate a change in case.

Key switches as used in keyboards must also operate reliably over a relatively long service life, and in many cases users desire keyboards with keys that have a desirable tactile feel. More specifically, many users prefer the feel of a key switch that provides at least some range real motion, such as 4 millimeters, so that the human user has a tactical awareness of the selected key being depressed, and then released.

But it is also to be appreciated that in many fields where traditional keyboards are used, speed and efficiency are often highly desired—such as for example in the field of multi person computer gaming. In addition, although most people do have two hands with ten fingers, there are people who have suffered a handicap and as such do not have use of two hands. Still further, that are situations where a person may be attempting to multi task with many different devices, and requiring both hands to be on a keyboard may be less efficient then otherwise desired. In short, a key switch that provides more than just one conductive trigger could be beneficial to many users in many settings.

Hence there is a need for a multi-position keyboard key switch that is capable of overcoming one or more of the above identified challenges.

### SUMMARY OF THE INVENTION

Our invention solves the problems of the prior art by providing a novel multi action key switch providing more than one conductive trigger.

In particular, and by way of example only, according to at least one embodiment, provided is a multi-position electrical switch including: an enclosure; a stem structured and arranged to move along a vertical axis within the housing, the stem providing a plurality of distinct horizontal protrusions as physical deactivators at different elevations along the vertical axis; a plurality of distinct electrical contacts, each contact provided by a paired stationary element and a movable element for flexibly making and breaking electrical contact with the stationary element, the movable element biased for contact with the stationary element, each distinct electrical contact associated with at least one distinct horizontal protrusion; and a spring disposing the stem in an initial position in which the plurality of distinct horizontal protrusions dispose all of the movable elements in broken contact; wherein depression of the stem along the vertical axis sequentially transitions the distinct horizontal protrusions away from the movable elements permitting contact with their paired stationary elements.

In yet another embodiment, provided is a multi-position electrical switch including: an enclosure provided by at least a bottom housing and a top housing, the top hosing having an aperture; a stem structured and arranged to move along a vertical axis within the housing through the aperture of the top housing, the stem providing a plurality of distinct pairs of horizontal fins at different elevations along the vertical axis, each fin having a first surface inclined towards the vertical axis, a plurality of distinct electrical contacts, each contact provided by a paired stationary element and a movable element for flexibly making and breaking electrical contact with the stationary element, the movable element biased for contact with the stationary element, each distinct electrical contact associated with one of the horizontal fins; and a spring disposed between the bottom housing and the stem, the spring disposing the stem in an initial position in which a portion of the plurality of first surfaces dispose all of the movable elements in broken contact; wherein motion of the stem along the vertical axis sequentially transitions the movable elements along the first surfaces of their associated fins to sequentially transition the movable elements and the stationary elements between making contact and breaking contact.

For yet another embodiment, provided is a multi-position electrical switch including: an enclosure provided by at least a bottom housing and a top housing, the top hosing having an aperture; a stem structured and arranged to move along a vertical axis within the housing through the aperture of the top housing, the stem providing a plurality of horizontal protrusions, the horizontal protrusions including at least; a first horizontal fin having a first surface at a first elevation along the vertical axis, the first surface inclined towards the vertical axis; a second horizontal fin having a second surface at a second elevation along the vertical axis different from the first elevation, the second surface inclined towards the vertical axis; a plurality of distinct electrical contacts, each contact provided by a paired stationary element and a movable element for flexibly making and breaking electrical contact with the stationary element, the movable element biased for contact with the stationary element, each distinct electrical contact associated with one of the horizontal protrusions; and a spring disposed between the bottom housing and the stem, the spring disposing the stem in an initial position in which each first surface and each third surface dispose all of the movable elements in broken contact; herein motion of the stem along the vertical axis sequentially transitions the movable elements between the first and second surfaces or third and fourth surfaces of their associated horizontal protrusions to sequentially transition the movable elements and the stationary elements between making contact and breaking contact.

### BRIEF DESCRIPTION OF THE DRAWINGS

FIGS. 1A and 1B are exploded perspective views of a multi-position switch in accordance with at least one embodiment of the present invention;

FIGS. 2A-2D are perspective, side, top, and front views of a stem element as incorporated in a multi-position switch in accordance with at least one embodiment of the present invention;

FIGS. 3A-3F are top, front, side, back, and perspective views of the stationary element of an electrical contact as incorporated in a multi-position switch in accordance with at least one embodiment of the present invention;

FIGS. 4A-4F are top, front, side, back, and perspective views of the movable element of an electrical contact electrical contact as incorporated in a multi-position switch in accordance with at least one embodiment of the present invention;

FIGS. 5A-5F are top, front, side, back, and perspective views of the electrical contact provided by a stationary element and movable element of an electrical contact as incorporated in a multi-position switch in accordance with at least one embodiment of the present invention;

FIGS. 6A-9C are progressive external views, partially exposed view and cut through views of a multi-position switch transitioning from an initial at rest position to a fully depressed position in accordance with at least one embodiment of the present invention; and

FIG. 10A-10D present conceptual illustrations of a fully assembled multi-position switch in accordance with at least one embodiment of the present invention;

### DETAILED DESCRIPTION

Before proceeding with the detailed description, it is to be appreciated that the present teaching is by way of example only, not by limitation. The concepts herein are not limited to use or application with a specific key switch. Thus, although the instrumentalities described herein are for the convenience of explanation shown and described with respect to exemplary embodiments, it will be understood and appreciated that the principles herein may be applied equally in other types of systems involving key switches and more specifically multi-position key switches for keyboards.

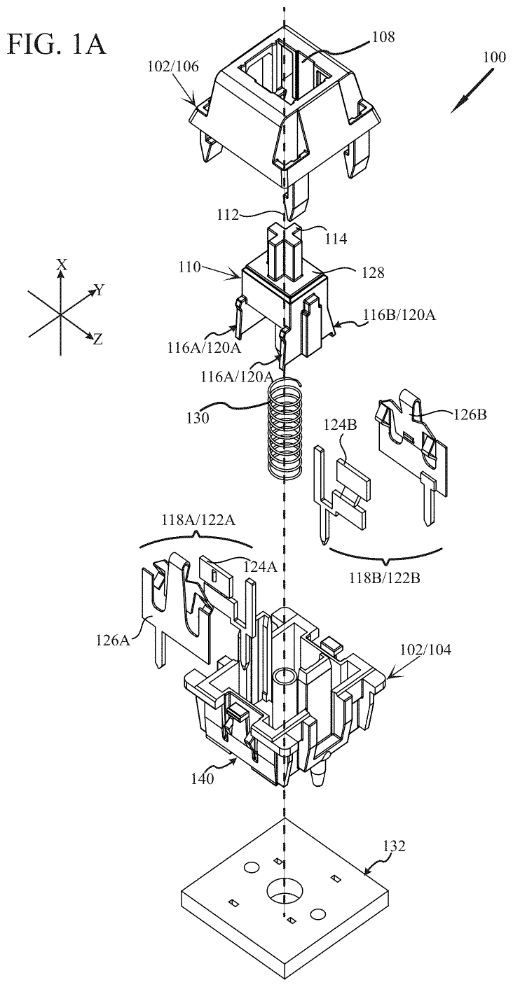

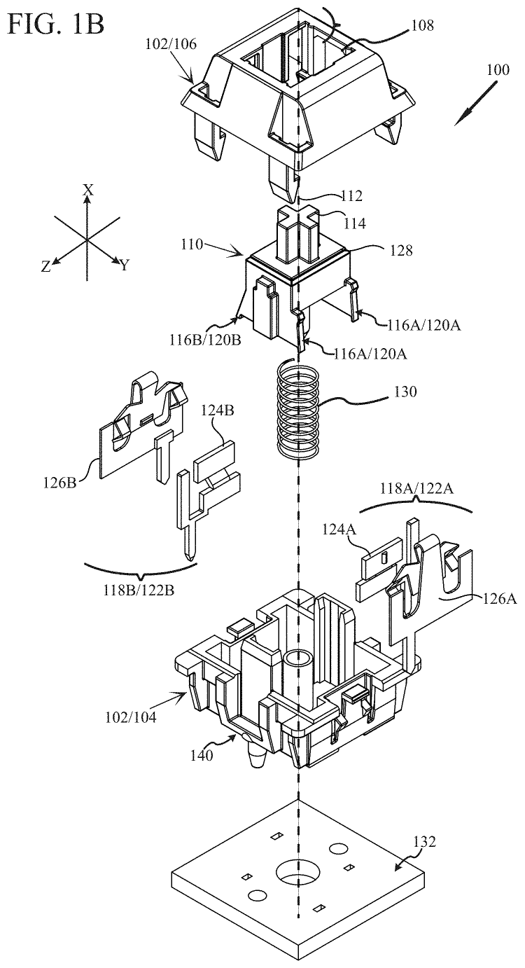

This invention is described with respect to preferred embodiments in the following description with reference to the Figures, in which like numbers represent the same or similar elements. Further, with respect to the numbering of the same or similar elements, it will be appreciated that the leading values identify the Figure in which the element is first identified and described, e.g., element 100 first appears in FIG. 1.

Turning now to the figures, FIGS. 1A and 1B present an exploded view of a multi-position switch 100, hereinafter MPS 100. To facilitate the description of systems and methods for this MD MPS SV 100 the orientation of MPS 100, as presented in the figures, is referenced to the coordinate system with three axes orthogonal to one another as shown in FIG. 1. The axes intersect mutually at the origin of the coordinate system, which is chosen to be the center of MPS 100, however the axes shown in all figures are offset from their actual locations for clarity and ease of illustration.

Returning to FIGS. 1A, and 1B it will be appreciated that the view in FIG. 1B is a 90-degree rotation of the view in FIG. 1A. As is shown in both FIG. 1A and FIG. 1B, for at least one embodiment, MPS 100 is provided at least in part by an enclosure 102 that is provided by at least a bottom housing 104 and a top housing 106. The top housing 106 has an aperture 108. A movable stem 110 is disposed within the housing 102 and structured and arranged to move along a vertical axis 112 within the housing 102, the distal end 114 of the stem 110 passing through the aperture 108 of the top housing 106.

For at least one embodiment, a key cap (not shown) providing indicia such as a letter, number, symbol, tactile element or the like is disposed upon the distal end 114 of the stem 110 when the MPS 100 is affixed to a printed circuit board or other structure so as to provide a key in a keyboard.

As may be appreciated, the stem 110 provides a plurality of horizontal protrusions 116 as physical deactivators at different elevations along the vertical axis 112. For the exemplary embodiment of MPS 100 as shown, there are two sets of horizontal protrusions 116A and 116B. In keeping with the exemplary depiction of two horizontal protrusions “A” and “B”, additional elements which will be understood and appreciated to be associated with horizontal protrusions “A” and “B” are also identified with an “A” or “B” for ease of distinction, but may be generally be referred to without the “A” or “B” in the continuing description.

Moreover, it will be understood and appreciated that the horizontal protrusions 116 provide a varying width to the stem 110. As will be further described below, for at least one embodiment this varying width acts in part as a mechanical element or lever to cause or break sequential connections between triggers 118 (such as but not limited to electrical contacts, inductive contact, capacitive contacts, optical sensors, or the like) which signal to the greater device that the key has been depressed—at least to a given point.

Because of varying widths provided by the horizontal protrusions 116, and different heights of these horizontal protrusions 116, different triggers 118 within the MPS 100 may be activated or deactivated at different elevations of the stem 110. Moreover, MPS 100 advantageously permits at least two sequential triggers 118 (shown in FIGS. 1A & 1B as triggers 118A and 118B) to be sequentially initiated during a single key depression and release by a user, dependent on the degree of key depression. In other words, for at least one embodiment, the first trigger 118A is activated and remains activated while the second trigger 118B is activated—as the user retracts pressure from the MPS 100, the second trigger 118 is released (sequentially deactivated) before the first trigger 118 is also released (sequentially deactivated).

Moreover, for at least one embodiment, the different triggers 118 are asymmetric, meaning that one can and will activate a contact or sensor before another contact or sensor is activated, and this activation is based on the degree of depression imparted to the stem 110. Further, an activated contact or sensor remains activated even as other contacts or sensors may be activated by other triggers 118, until such time as the depression of the stem 110 is released past the point of trigger activation.

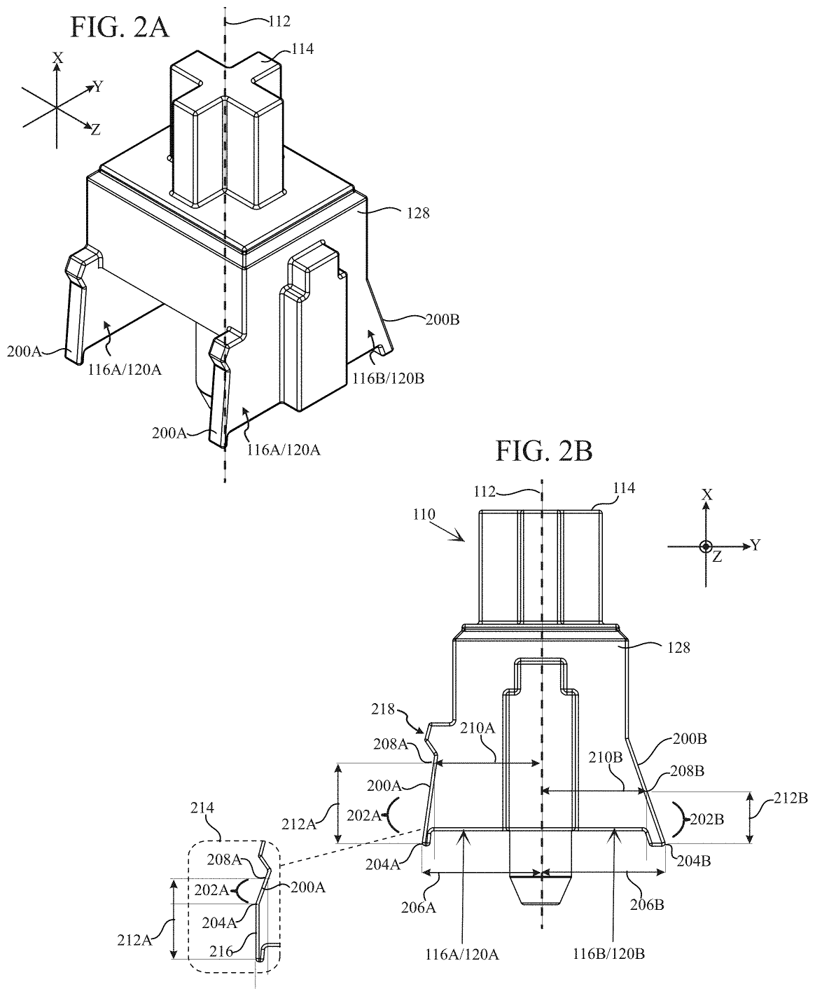

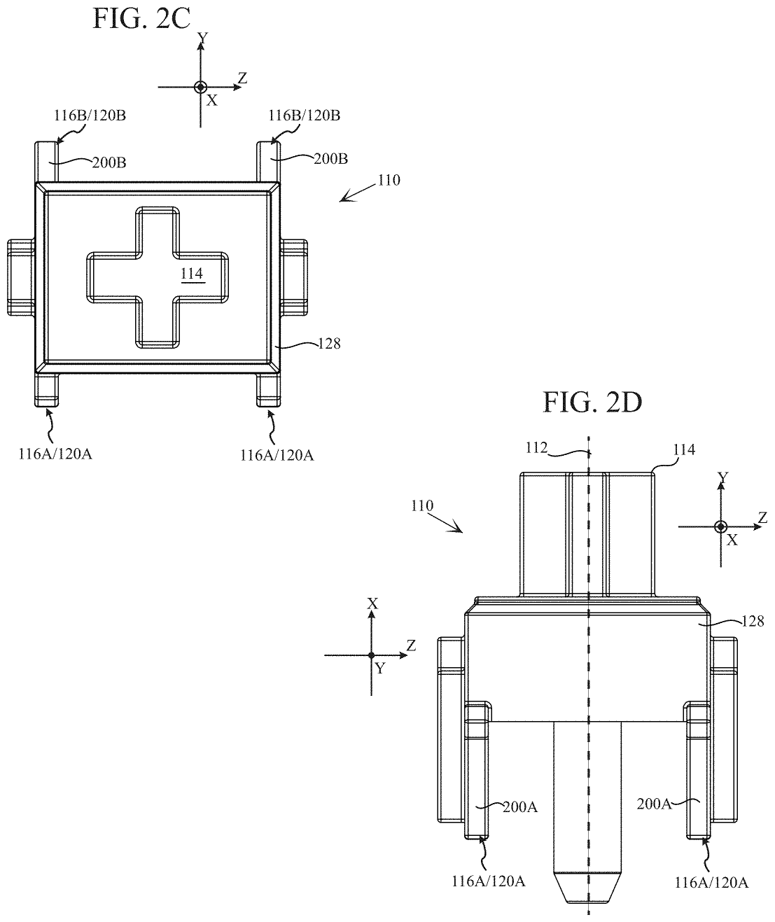

For at least one embodiment, the horizontal protrusions 116 are horizontal fins 120, again shown as fins 120A and 120B to correlate to the two horizontal protrusions and triggers as shown, the fins 120 further described below with respect to FIGS. 2A-2D.

Although a varying option of triggers 118 may be employed in various embodiments, for at least one embodiment MPS 100 enjoys the use of physical electrical contacts 122, which by their very nature provide an advantage for easy tactile feedback to the user, as well as a simplistic electrical/mechanical configuration that is low cost and well known for longevity of performance.

Moreover, for at least one embodiment, the triggers 118, e.g., exemplary trigger 118A and trigger 118B, are distinct electrical contacts 122, each contact 122 provided by a paired stationary element 124 and a movable element 126 for flexibly making and breaking electrical contact with the stationary element 124. For at least one embodiment, each movable element 126 is biased for contact with the stationary element 124.

More specifically, as shown in FIGS. 1A and 1B, there are two electrical contacts 122 of which 122A and 122B are exemplary. Electrical contact 122A is provided by paired stationary element 124A and movable element 126A. Likewise, electrical contact 122B is provided by paired stationary element 124B and movable element 126B.

It will also be appreciated from FIGS. 1A and 1B that electrical contact 122A is generally aligned to horizontal protrusions 116A and electrical contact 122B is generally aligned to horizontal protrusions 116B, and for the exemplary embodiment as depicted these paired sets of horizontal protrusions 116 and electrical contacts 122 are on opposing sides of stem 110, shown to have a generally square core 128. For at least one alternative embodiment, the paired horizontal protrusions 116 and electrical contacts 122 may be disposed at right angles to one another (e.g., on adjacent sides of the square core 128), not shown.

It will also be understood and appreciated, that in varying embodiments, the general structure of MPS 100 as shown could be modified to include an additional one or two pairs of horizontal protrusions 116 and electrical contacts 122 along three or four sides of the square core 128. Moreover, it will be understood and appreciated that varying embodiments of MPS 100 may be configured to provide at least two to four different contacts. Indeed, it will be understood and appreciated that changes to the cross-section geometry of the core 128—such as for a triangle, pentagon, or hexagon may provide convenient alignment surfaces for embodiments of MPS 100 having a varying plurality of distinct trigger points during depression of the stem 110.

For at least one embodiment, at least one spring 130 is disposed between the stem 110 and the bottom housing 104. This at least one spring 130 disposes the stem 110 in an initial position in which the plurality of distinct horizontal protrusions 116 dispose all of the movable elements 126 in broken contact. In other words, in the initial position of stem 110 as established by the at least one spring 130, all of the stationary elements 124 and their associated movable elements 126 of each distinct electrical contact 122 are disposed apart from each other, such that no electrical contact is made.

MPS 100 is generally affixed to a portion of a circuit board 132, aka PCB 132, which in at least one embodiment has been set to receive and support the bottom housing 140 as well as electrical contact leads from each electrical contact 122.

As noted above, FIGS. 2A-2D present views of the stem 110. Specifically, FIG. 2A presents a perspective view similar to that of FIG. 1A, with FIG. 2B presenting a side to further appreciate the horizontal protrusions 116. FIG. 2C presents a top view and FIG. 2D presents a 90-degree rotation of the view in FIG. 2B. With respect to FIGS. 2A-2D, it will be appreciated that stem 110 is not symmetrical, at least with respect to horizontal protrusions 116.

As may be most clearly appreciated in the side view of FIG. 2C, the profile of the two exemplary horizontal protrusions 116, aka horizontal fins 120, is quite different. Each fin 120 having at least a first surface 200 that is inclined towards the vertical axis 112. It is also to be appreciated that as this first surface 200 is inclined towards the vertical axis 112, at least a portion 202 of the first surface 200 is therefore disposed away from the vertical axis 112.

More simply put, each horizontal fin 120 has a first surface 112 that extends from generally a first point 204 a first distance 206 away from the vertical axis 112 to a second point 208 a second distance 210 away from the vertical axis 112, the second distance 210 being less than the first distance 206. As such, first surface 112 is an inclined surface such that relative movement along the vertical axis 112 corresponds to points along the inclined surface that are closer to or farther away from the vertical axis 112.

With respect to FIG. 2B, it will be easily appreciated that second point 208A for fin 120A is at a height 212A that is substantially above the height 212B of second point 208B for fin 120B, and as is also shown, the relative change between distance 206B and 210B is greater than the relative change between distance 206A and 210A. Simply put, it is difference in this change in distance from the vertical axis 112 at different points along the first surface 200A vs. first surface 200B that allows the horizontal protrusions 116A, aka horizontal fins 120A to have a distinctly different trigger point from the horizontal protrusions 116B, aka horizontal fins 120B. It is these trigger points along horizontal protrusion 116 that transitions the state of the electrical contact 122 from breaking to making contact and vice versa.

In varying embodiments, each horizontal fin 120 may or may not have a surface that is essentially parallel to the vertical axis 112. For such embodiments, such a parallel surface is of course understood and appreciated as a surface that remains equidistant from the vertical axis 112 along its entire length. Further still, varying embodiments might present a stair step arrangement of the horizontal protrusions 116, inclined surfaces are generally appreciated to help the mechanical elements glide smoothly against one another in embodiments of MPS 100 reliant upon mechanical interaction between elements.

As first stated above, and now shown in the optional dotted rounded rectangle 214 of FIG. 2B, for at least one embodiment, one or more of the horizontal protrusions 116 may include a surface that is essentially parallel to the vertical axis 112, such as second surface 216 for horizontal protrusion 116A. As this second surface 216 is parallel to the vertical axis 112, during movement of the stem 110 along the vertical axis 112. When the second surface 216 transitions to the first surface 200A at point 204A, as first surface 200A is inclined towards the vertical axis 112, a change in horizontal distance occurs once again and the transition from breaking to making contact occurring at the transition points 208A, which again will be appreciated to be at different height—212A, relative to height 212B transition point 208B.

One or more of the horizontal protrusions 116 may also include a tactile feature, such as feature 218, which is structured and arranged in such a way so as to cause the user to feel through their fingertip that a depression level has been achieved. Feature 218 may also be an audible indicator, such as a click plate.

As may further be appreciated in FIGS. 2A-2D, for at least one embodiment each horizontal protrusion 116 is actually a matched set of protrusions which operate collective as one. As keyboard keys are generally required to have a long life of performance, many manufacturers have found the parallel elements to have greater longevity and reliability of performance. However, it is to be expressly understood and appreciated, that the present invention is not limited to embodiments having paired horizontal protrusion 116. Moreover, for at least one embodiment a single horizontal protrusion 116 may be provided for each physical deactivator, while for yet another embodiment, more than two elements may cooperatively operate as each horizontal protrusion 116.

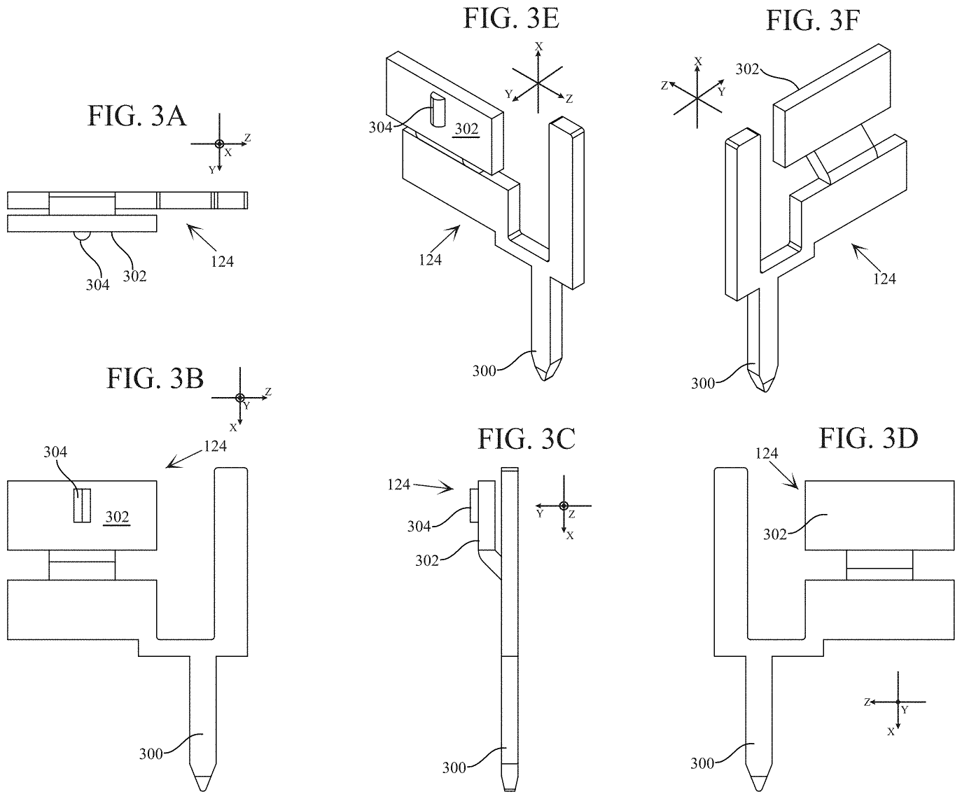

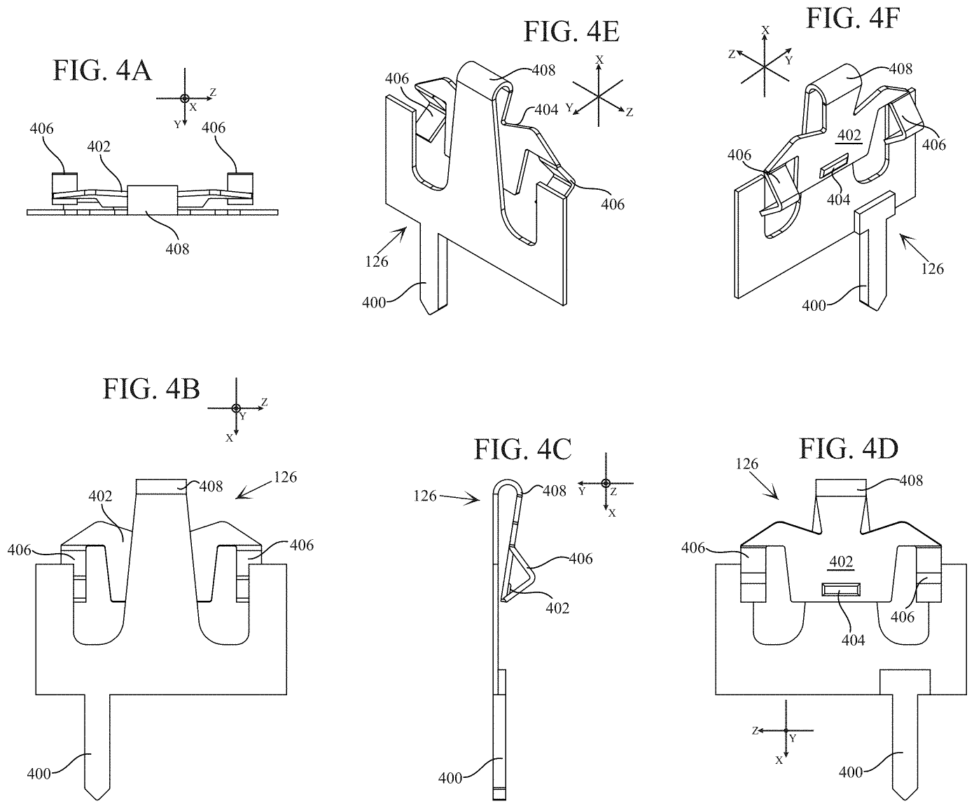

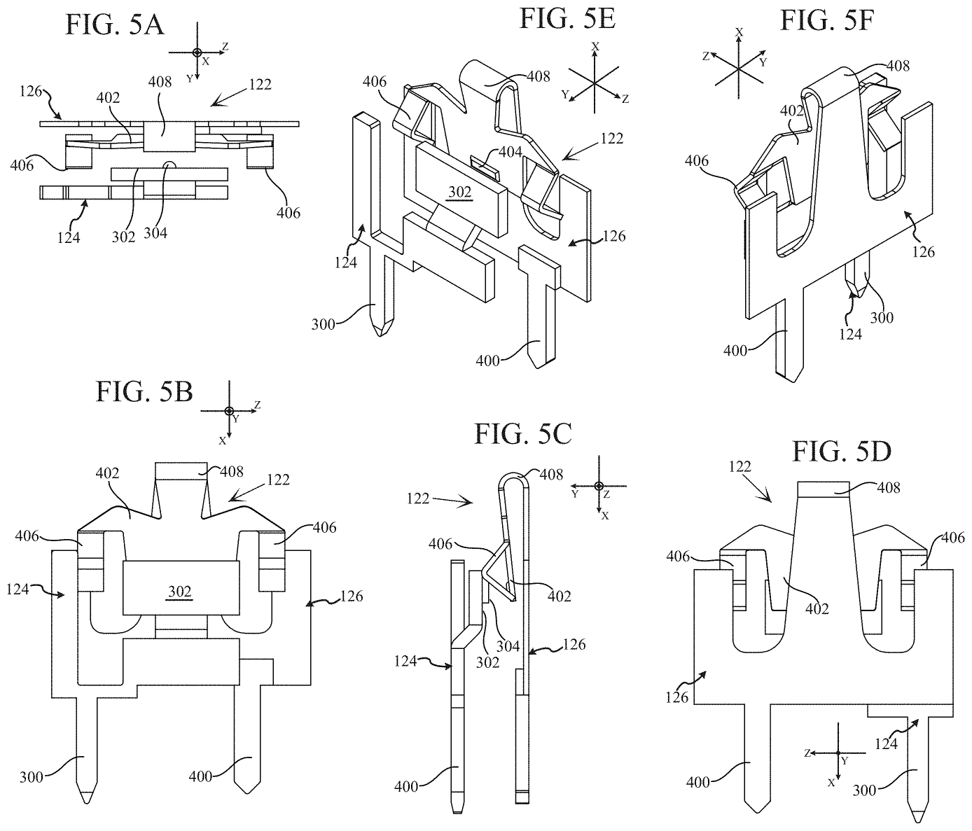

FIG. 3A-5F presents an enlarged view of electrical contact 122 with, FIGS. 3A-3F providing enlarged views of the stationary element 124, FIGS. 4A-4F providing similar enlarged views of movable element 126, and FIGS. 5A-5F providing similar enlarged views of electrical contact 122 as provided by stationary element 124 and movable element 126.

Moreover, for at least one embodiment, stationary element 124 is appreciated to have a lead 300 and a contact area 302, if not an actual contact pad(s) 304. For at least one embodiment, stationary element 124 is essentially a metallic element provided as a cut or stamped element. In varying embodiments, stationary element 124 may be formed from, but not limited to, copper, aluminum, silver, zinc, or other metals. FIG. 3A provides a top view, FIG. 3B provides a front view, FIG. 3C provides a side view, FIG. 3D provides a back view and FIGS. 3E and 3F provide opposing perspective views.

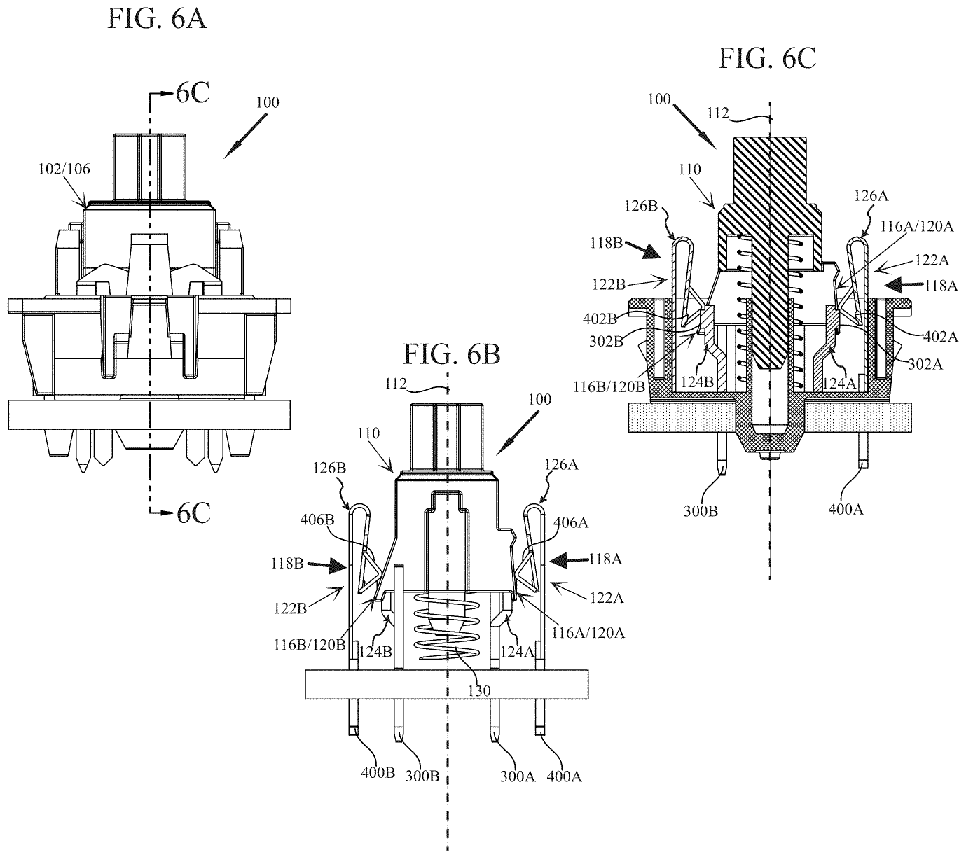

As shown in FIGS. 4A-4F, the movable element 126 is also appreciated to have a lead 400. For at least one embodiment, movable element 126 may be described as a biased spring element where the contact area 402, if not an actual contact pad(s) 404, and at least one cam 406 are disposed on, or as part of the movable spring end 408. As is further shown below with respect to FIGS. 6A-6D the at least one cam 406 is structured and arranged for sliding contact with the horizontal protrusion 116 as provided by the stem 110.

For at least one embodiment, movable element 126 is essentially a metallic element provided as a cut or stamped element. In varying embodiments, movable element 126 may be formed from, but not limited to, copper, aluminum, silver, zinc, or other metals. FIG. 4A provides a top view, FIG. 4B provides a back view, FIG. 4C provides a side view, FIG. 4D provides a front view and FIGS. 4E and 4F provide opposing perspective views.

FIGS. 5A-5F essentially combine the illustrations of the stationary element 124 as shown in FIGS. 3A-3F and the movable element 126 as shown in FIGS. 4A-4F, as a functional electrical contact 122. FIG. 5A provides a top view, FIG. 5B provides a front view, FIG. 5C provides a side view, FIG. 5D provides a back view and FIGS. 5E and 5F provide opposing perspective views.

With respect to lead 300 of the stationary element 124 and lead 400 of the movable element 126, leads 300 and 400 extend through openings in the bottom of the housing 104 (see FIGS. 1A & 1B) to conductively connect the electrical contact 122 with an associated circuit (not shown). As the associated circuit may in at least one embodiment be provided by a printed circuit board, when the leads 300 and 400 are attached, such as by solder, it will be appreciated that leads 300 and 400 may also serve to mount and support MPS 100.

When disposed within the bottom housing 104 of the MPS 100, the stationary element 124 and movable element 126 are so positioned contact areas 302 and 402 are disposed apart when the stem 110 is in released or initial position, and in physical contact when the stem 110 has been depressed such that the horizontal protrusion 116 associated with the electrical contact 122 has been disposed away from its initial deactivator position.

For at least one embodiment, the electrical contacts 122 within the MPS 100 are substantially identical, such that the enlarged electrical contact 122 comprised of the stationary element 124 and the movable element 126 shown in FIG. 3A-5F may be either the electrical contact 122A or electrical contact 122B as shown in FIGS. 1A and 1B.

Returning to FIGS. 1A and 1B, as the stem 110 is depressed by a user, the stem 110 travels along the vertical axis 112. As the stem 110 travels along the vertical axis 112 it transitions the distinct horizontal protrusions 116 away from the movable elements 126 and allows each movable element 126 to make electrical contact with its associated stationary element 124. As the distinct horizontal protrusions 116 are at different relative elevations along the stem 110, for at least one embodiment the movable element 126B will make contact with stationary element 124B of electrical contact 122B before the movable element 126A will make contact with stationary element 124A of electrical contact 122A.

As the user release the stem 110, the at least one spring 130 drives the stem 110 back up along the vertical axis 112 and in so doing sequentially repositions the distinct horizontal protrusions 116 to dispose the movable elements 126 away from their paired stationary elements 124 of each electrical contact 122.

In short, for at least one embodiment, MPS 100 may be summarized as including: an enclosure 102; a stem 110 structured and arranged to move along a vertical axis 112 within the enclosure 102, the stem 110 providing a plurality of distinct horizontal protrusions 116 as physical deactivators at different elevations along the vertical axis 112; a plurality of distinct electrical contacts 122, each contact provided by a paired stationary element 124 and a movable element 126 for flexibly making and breaking electrical contact 122 with the stationary element 124, the movable element 126 biased for contact with the stationary element 124, each distinct electrical contact 122 associated with at least one distinct horizontal protrusion; and a spring disposing the stem 110 in an initial position in which the plurality of distinct horizontal protrusions 116 dispose all of the movable elements 126 in broken contact; wherein depression of the stem 110 along the vertical axis 112 transitions the distinct horizontal protrusions 116 away from the movable elements 126 permitting contact with their paired stationary elements 124.

For yet another embodiment, MPS 100 may be summarized as including: an enclosure 102 provided by at least a bottom housing and a top housing, the top hosing having an aperture; a stem 110 structured and arranged to move along a vertical axis 112 within the housing through the aperture of the top housing, the stem 110 providing a plurality of distinct pairs of horizontal fins, each fin having a first surface inclined towards the vertical axis 112, a plurality of distinct electrical contacts 122, each contact provided by a paired stationary element 124 and a movable element 126 for flexibly making and breaking electrical contact 122 with the stationary element 124, the movable element 126 biased for contact with the stationary element 124, each distinct electrical contact 122 associated with one of the horizontal fins; and a spring disposed between the bottom housing and the stem 110, the spring disposing the stem 110 in an initial position in which a portion of the plurality of first surfaces dispose all of the movable elements 126 in broken contact; wherein motion of the stem 110 along the vertical axis 112 transitions the movable elements 126 along the first surfaces of their associated fins to transition the movable elements 126 and the stationary elements 124 between making contact and breaking contact.

Moreover, with respect to the above description of the physical elements for at least one exemplary embodiment of MPS 100 having two (2) distinct triggers 118 structured and arranged for activation and deactivation at distinctly different points of vertical travel by the stem 110 along the central access, FIGS. 6A-C through 9A-C provide a conceptualized walk through of exemplary use of at least the one exemplary MPS 100.

More specifically, FIGS. 6A-6C illustrate an embodiment of MSP 100 as described above, having two distinct triggers 118, provided by two distinct electrical contacts 126, specifically electrical contacts 126A and 126B which are in paired alignment with horizontal protrusions 116A and 116B from stem 110.

FIG. 6A is a first external side view of MSP 100 in its initial at rest/non-depressed state. As such spring 130 is expanded to naturally dispose the stem 110 in its upward most position within the housing 102.

As shown in FIG. 6B as a partially exposed view, in this initial at rest/non-depressed state, horizontal protrusion 116A is disposed against cam 406A and horizontal protrusion 116B is disposed against cam 406B. FIG. 6B is a 90-degree rotation of the MSP 100 in FIG. 6A so as to appreciate the bisection that is shown in FIG. 6C. As illustrated in FIG. 6C, the contact areas 302A/402A and 302B/402B are disposed apart and therefore no electrical contact is presently occurring.

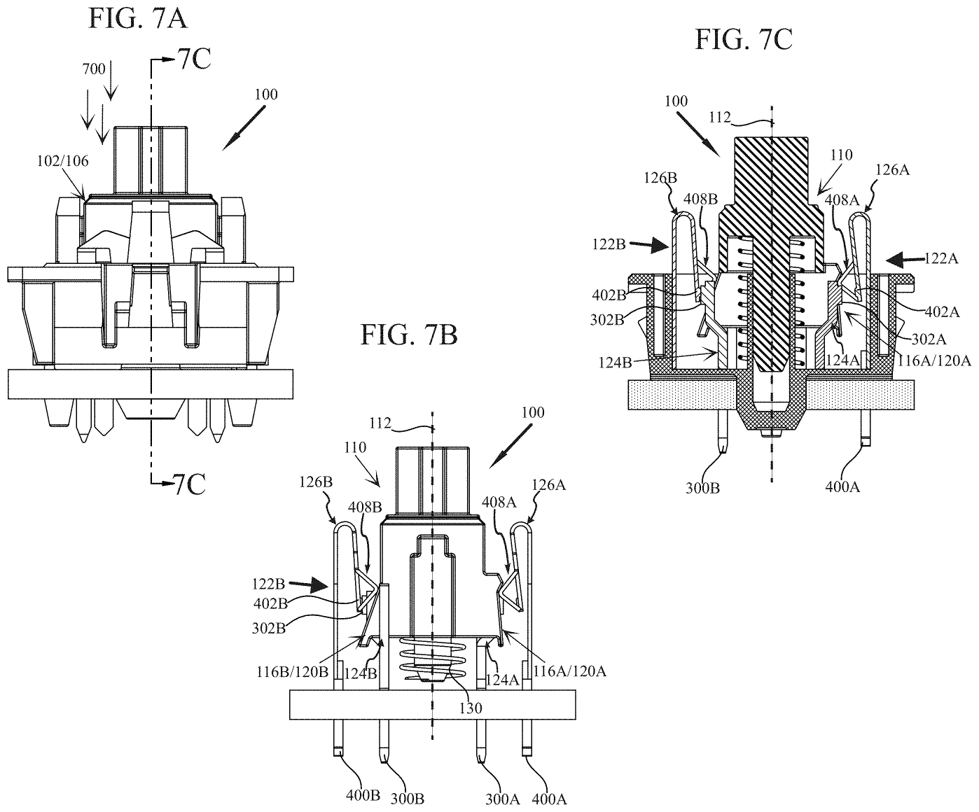

FIG. 7A is a similar first side view of MSP 100, but now a downward force 700 has been applied to the stem 110 such that stem 100 has traveled some vertical distance along vertical axis 112. FIG. 7B is again a 90-Degree rotation and partially exposed view of the MSP 100 in FIG. 7A so as to appreciate the bisection that is shown in FIG. 7C.

As illustrated in FIG. 7C, the contact points 302B/402B are now in physical contact as the horizontal protrusion 116A has been disposed below cam 308B. However, contact points 302A/402A remain disposed apart because cam 308A and horizontal protrusion 116A as still in sufficient alignment that horizontal protrusion 116A remains active as a physical deactivator.

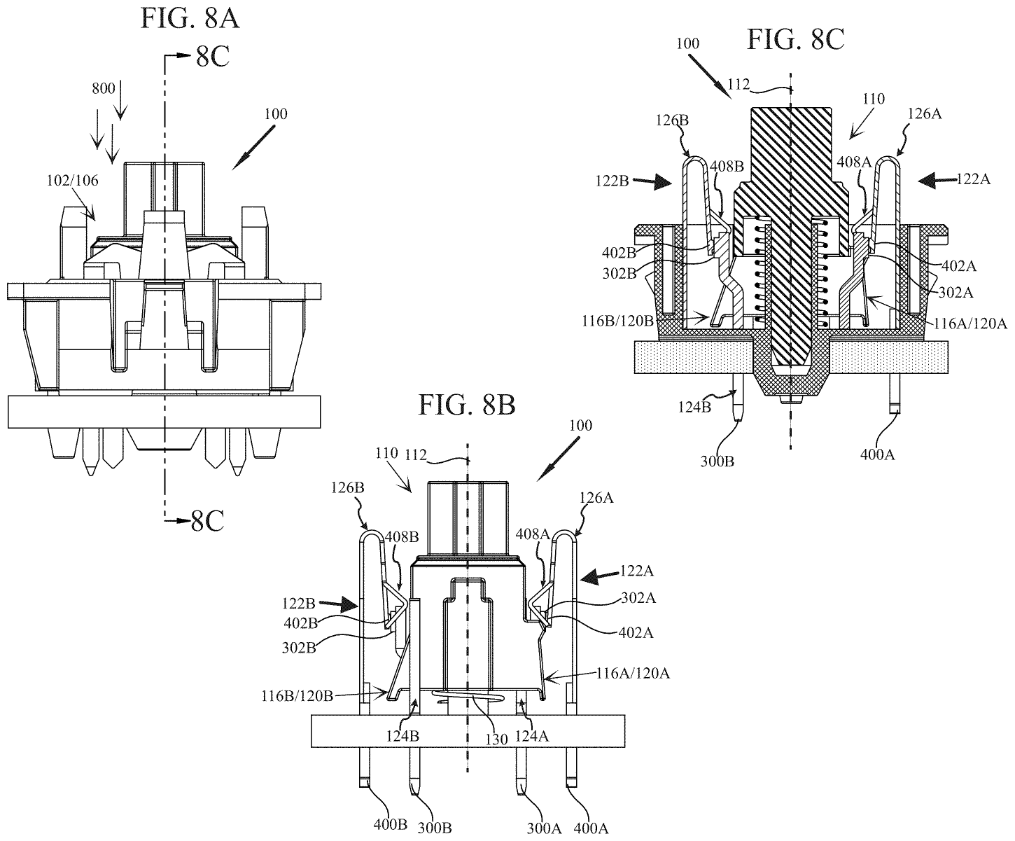

FIG. 8A is a similar first side view of MSP 100, but now progressed from the state shown in FIG. 7A. Moreover, the downward force 800 has continued such that stem 100 has traveled a further vertical distance along vertical axis 112. FIG. 8B is again a 90-Degree rotation and partially exposed view of the MSP 100 in FIG. 8A so as to appreciate the bisection that is shown in FIG. 8C.

As illustrated in FIG. 8C, the contact points 302B/402B are still in physical contact as the horizontal protrusion 116B is still disposed below cam 408B. Now as well, contact points 302A/402A are in physical contact as horizontal protrusion 116A has been disposed below cam 408A.

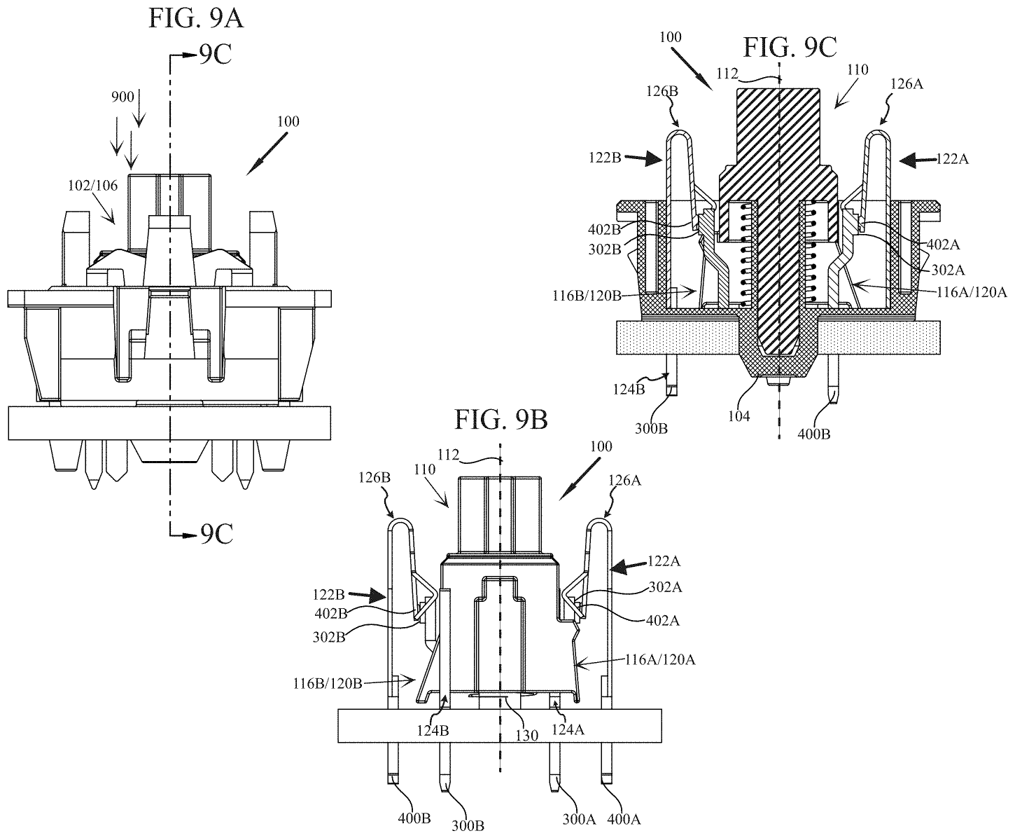

FIGS. 9A-9C are conceptual renderings of MSP 100 as shown in FIGS. 8A-8C, only now the application of continued force 900 has the stem 110 has physically impacted some portion of the bottom housing 104, or spring 130 has been completely compressed such that no further depression of stem 110 is generally possible.

With respect to the above description, it may also be understood and appreciated that a second spring (not shown) may be disposed about spring 130 with a relative height of 212B, such that the user feels an increased resistive force when depressing the stem 110 past the trigger 118 established by horizontal protrusion 116B and further displacing horizontal protrusion 116A.

With respect to the above description of FIGS. 6A-C through 9A-C with respect to two triggers 118, it will be understood and appreciated that the same methodology of physical performance may be extrapolated to embodiments of MPS 100 incorporating a plurality of triggers 118 beyond the present exemplary embodiment of two.

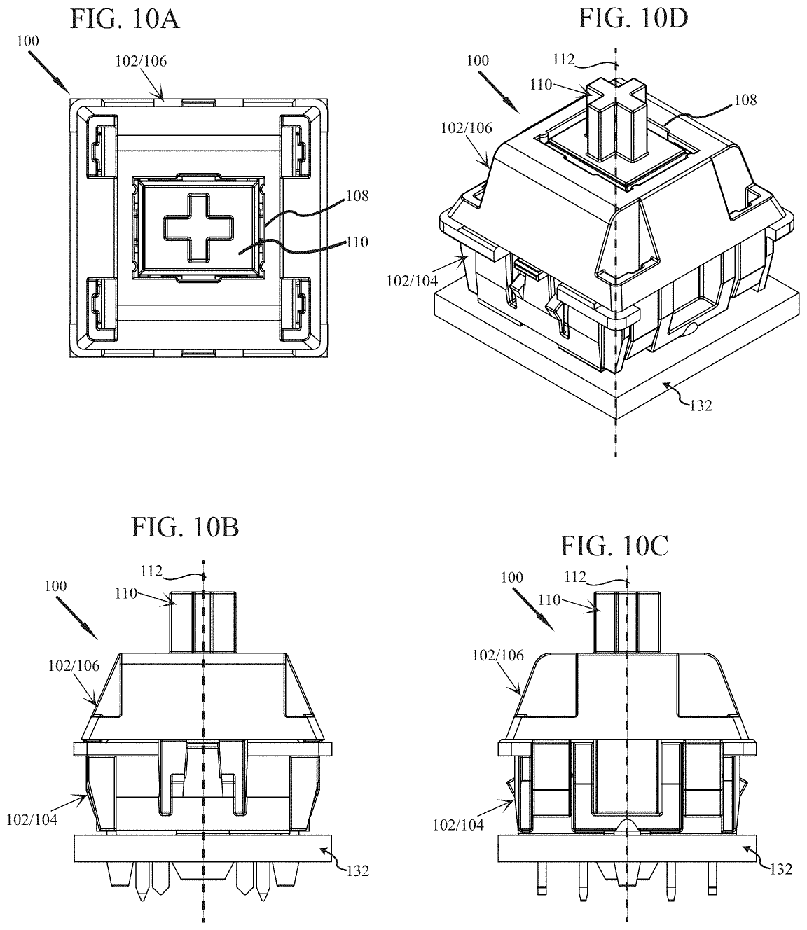

FIGS. 10A-10D present conceptual illustrations of a fully assembled MPS 100 as described above. More specifically, FIG. 10A is a top view, FIG. 10B is a front view, FIG. 10C is a side view, and FIG. 10D is a top perspective view.

Changes may be made in the above methods, systems and structures without departing from the scope hereof. It should thus be noted that the matter contained in the above description and/or shown in the accompanying drawings should be interpreted as illustrative and not in a limiting sense. Indeed, many other embodiments are feasible and possible, as will be evident to one of ordinary skill in the art. The claims that follow are not limited by or to the embodiments discussed herein, but are limited solely by their terms and the Doctrine of Equivalents.

What is claimed:

1. A multi-position switch comprising:
an enclosure;
a stem structured and arranged to move along a vertical axis within the housing, the stem providing a plurality of distinct horizontal protrusions as physical deactivators at different elevations along the vertical axis;
a plurality of distinct electrical contacts, each contact provided by a paired stationary element and a movable element for flexibly making and breaking electrical contact with the stationary element, the movable element biased for contact with the stationary element, each distinct electrical contact associated with at least one distinct horizontal protrusion; and
a spring disposing the stem in an initial position in which the plurality of distinct horizontal protrusions dispose all of the movable elements in broken contact;
wherein depression of the stem along the vertical axis sequentially transitions the distinct horizontal protrusions away from the movable elements permitting contact with their paired stationary elements.

2. The multi-position switch of claim 1, wherein each distinct horizontal protrusion has a substantially normal surface and an inclined surface, the normal surface structured and arranged to dispose the movable element apart from the stationary element, the inclined surface structured and arranged to transition the movable element and the stationary element between making contact and breaking contact.

3. The multi-position switch of claim 2, having at least a first horizontal protrusion paired with a first electrical contact and a second horizontal protrusion paired with a second electrical contact, the first horizontal protrusion having a first normal element with a first length and the second horizontal protrusion having a second normal element with a second length, the second length greater than the first length, the first horizontal protrusion permitting contact between a first movable element and a first stationary element in a first range of vertical motion of the stem along the axis, the second horizontal protrusion permitting contact between a second movable element and a second stationary element in a second range of vertical motion of the stem along the axis.

4. The multi-position switch of claim 3, having at least one additional horizontal protrusion paired with an electrical contact, the additional horizontal protrusion having an additional horizontal surface having an additional length different from the first length and the second length.

5. The multi-position switch of claim 1, providing at least two sequentially activated electrical contacts.

6. The multi-position switch of claim 1, wherein the enclosure is provided by a bottom housing and top housing, the top having an aperture, the stem extending through the aperture.

7. The multi-position switch of claim 1, wherein conductive leads extend from each electrical contact for mounting to a printed circuit board.

8. The multi-position switch of claim 1, further including a tactile indicator between at least two of the distinct horizontal protrusions.

9. The multi-position switch of claim 1, further including an audible indicator between at least two of the distinct horizontal protrusions.

10. The multi-position switch of claim 1, wherein a plurality of the multi contact electrical switches are incorporated as keys for a computer keyboard, each multi-position switch permitting each key to have one or more values based on the degree of vertical travel of each stem.

11. The multi-position switch of claim 1, wherein contact between each paired movable element and stationary element remains until release of the stem returns the horizontal protrusion to dispose each movable element apart from its paired stationary element.

12. A multi-position switch comprising:
an enclosure provided by at least a bottom housing and a top housing, the top hosing having an aperture;
a stem structured and arranged to move along a vertical axis within the housing through the aperture of the top housing, the stem providing a plurality of distinct pairs of horizontal fins at different elevations along the vertical axis, each fin having a first surface inclined towards the vertical axis;
a plurality of distinct electrical contacts, each contact provided by a paired stationary element and a movable element for flexibly making and breaking electrical contact with the stationary element, the movable element biased for contact with the stationary element, each distinct electrical contact associated with one of the horizontal fins; and
a spring disposed between the bottom housing and the stem, the spring disposing the stem in an initial position in which a portion of the plurality of first surfaces dispose all of the movable elements in broken contact;
wherein motion of the stem along the vertical axis sequentially transitions the movable elements along the first surfaces of their associated fins to sequentially transition the movable elements and the stationary elements between making contact and breaking contact.

13. The multi-position switch of claim 12, having at least a first paired fin set associated with a first electrical contact and a second paired fin set associated with a second electrical contact, the first paired fin set having first normal elements with a first length and the second paired fin set having second normal elements with a second length, the second length greater than the first length, the first paired fin set permitting contact between a first movable element and a first stationary element in a first range of vertical motion of the stem along the axis, the second paired fin set permitting contact between a second movable element and a second stationary element in a second range of vertical motion of the stem along the axis.

14. The multi-position switch of claim 12, providing at least two sequentially activated electrical contacts.

15. The multi-position switch of claim 12, wherein conductive leads extend from each electrical contact for mounting to a printed circuit board.

16. The multi-position switch of claim 12, further including a tactile indicator between at least two of the distinct horizontal protrusions.

17. The multi-position switch of claim 12, further including an audible indicator between at least two of the distinct horizontal protrusions.

18. The multi-position switch of claim 12, wherein a plurality of the multi contact electrical switches are incorporated as keys for a computer keyboard, each multi-position switch permitting each key to have one or more values based on the degree of vertical travel of each stem.

19. The multi-position switch of claim 12, wherein contact between each paired movable element and stationary element remains until release of the stem returns the horizontal protrusion to dispose each movable element apart from its paired stationary element.

20. A multi-position switch comprising:
an enclosure provided by at least a bottom housing and a top housing, the top hosing having an aperture;
a stem structured and arranged to move along a vertical axis within the housing through the aperture of the top housing, the stem providing a plurality of horizontal protrusions, the horizontal protrusions including at least;
a first horizontal fin having a first surface at a first elevation along the vertical axis, the first surface inclined towards the vertical axis;
a second horizontal fin having a second surface at a second elevation along the vertical axis different from the first elevation, the second surface inclined towards the vertical axis;
a plurality of distinct electrical contacts, each contact provided by a paired stationary element and a movable element for flexibly making and breaking electrical contact with the stationary element, the movable element biased for contact with the stationary element, each distinct electrical contact associated with one of the horizontal protrusions; and
a spring disposed between the bottom housing and the stem, the spring disposing the stem in an initial position in which each first surface and each third surface dispose all of the movable elements in broken contact;
wherein motion of the stem along the vertical axis sequentially transitions the movable elements between the first and second surfaces or third and fourth surfaces of their associated horizontal protrusions to sequentially transition the movable elements and the stationary elements between making contact and breaking contact.

21. The multi-position switch of claim 20, providing at least two sequentially activated electrical contacts.

22. The multi-position switch of claim 20, wherein each fin has a matching twin, the twin fins operating as a paired set to transition the movable element between making contact and breaking contact.

23. The multi-position switch of claim 20, wherein conductive leads extend from each electrical contact for mounting to a printed circuit board.

24. The multi-position switch of claim 20, further including a tactile indicator between at least two of the distinct horizontal protrusions.

25. The multi-position switch of claim 20, further including an audible indicator between at least two of the distinct horizontal protrusions.

26. The multi-position switch of claim 20, wherein a plurality of the multi contact electrical switches are incorporated as keys for a computer keyboard, each multi-position switch permitting each key to have one or more values based on the degree of vertical travel of each stem.

27. The multi-position switch of claim 20, wherein contact between each paired movable element and stationary element remains until release of the stem returns the horizontal protrusion to dispose each movable element apart from its paired stationary element.
